(19) United States
(12) Patent Application Publication
(10) Pub. No.: US 2012/0207916 A1
(43) Pub. Date: Aug. 16, 2012

(54) APPARATUS AND METHOD FOR COOLING OR HEATING WORK PIECE IN A VACUUM CHAMBER

(76) Inventor: George X. Guo, Palo Alto, CA (US)

(21) Appl. No.: 13/171,728

(22) Filed: Jun. 29, 2011

Related U.S. Application Data
(60) Provisional application No. 61/443,583, filed on Feb. 16, 2011.

(51) Int. Cl. H05K 3/22; C23C 16/44

(52) U.S. Cl. 427/96.8; 118/725; 427/255.28

(57) ABSTRACT

A vacuum processing system includes a vacuum chamber in connection with a vacuum pump that can exhaust air or vapor in the vacuum chamber, and a container in the vacuum chamber configured to contain one or more work pieces therein and to receive a heat-exchange liquid that comes into contact with the one or more work pieces to allow heat exchange with the one or more work pieces. The vacuum pump can exhaust at least a portion of the vapor evaporated from the heat-exchange liquid on the work pieces or in the container. A deposition source unit can provide material to be deposited on the one or more work pieces in vacuum. The one or more work pieces can be brought a predetermined temperature by the heat-exchange liquid.

The present application claims priority to pending U.S. Provisional Patent Application 61/443,583, entitled “Apparatus and method for cooling or heating work piece in a vacuum chamber”, filed by the same inventor on Feb. 16, 2011, the disclosures of which is incorporated herein by reference.

### BACKGROUND OF THE INVENTION

The present application relates to technologies for cooling or heating work pieces inside a vacuum environment such as a vacuum chamber for material depositions.

Material deposition is widely used in window glass coating, light emitting diode (LED), circuit boards, flat panel display manufacturing, coating on flexible films (such as webs), hard disk coating, industrial surface coating, semiconductor wafer processing, photovoltaic panels, and other applications. To receive deposition, the substrate usually needs to be cooled or heated to a certain temperature to enable deposited material to possess desirable properties. Heating and cooling the substrate, however, can be difficult inside a vacuum environment because there is almost no air to produce convective heat exchange. Heat transfer in vacuum is usually accomplished by radiation. The tasks of heating and cooling substrates in vacuum can be especially challenging when multiple work pieces are stacked together such that some work pieces are shielded from direct radiation for the heating or cooling elements.

Conduction-based heat exchange also has drawbacks. A flat surface is required on the work pieces to provide contact area with the heating/cooling elements, which is not suitable for irregularly shaped work pieces such as circuit boards. Moreover, heat conduction can process few work pieces at a time.

Cooling a work piece in vacuum is generally more difficult than heating because the maximum temperature difference between cooling elements and work piece is small compared to heating. Moreover, water condensation on the work piece surfaces from residue water in the vacuum system can also affect the quality of coating. Additionally, the contact with a cold surface in conduction-based cooling is often a source of contamination to the work pieces.

There is therefore a need to provide efficient, and preferably simple, methods for cooling and heating work pieces in a vacuum environment such as vacuum deposition systems.

### SUMMARY OF THE INVENTION

The presently disclosed systems and methods can provide fast cooling and heating to work pieces in a vacuum environment. Moreover, the fast cooling and heating can be performed on a large number of work pieces, which further reduces operation times.

The presently disclosed systems require fewer components than conventional systems. The cooling can be accomplished using equipment such as vacuum pump which already exists in the vacuum processing systems.

The presently disclosed systems and methods can protect work piece surfaces from contamination in the environment, which is often an issue, as described above, in conventional conduction-based cooling techniques.

Moreover, the presently disclosed systems and methods are suitable to work pieces of any shape including irregular shaped objects such as printed circuit boards (PCBs).

Furthermore, the presently disclosed systems and methods are more efficient and consume less energy to operate.

The disclosed systems can provide effective cooling and heating in a wide range of vacuum systems such as thin-film deposition, substrate etching, sputtering using DC (direct current)/RF (radio frequency) diode or magnetron, chemical vapor deposition (CVD), plasma enhanced chemical vapor deposition (PECVD), sputter etch, plasma etch, or reactive ion etch.

In one general aspect, the present invention relates to a vacuum processing system that includes a vacuum chamber in connection with a vacuum pump that can exhaust air or vapor in the vacuum chamber, and a container in the vacuum chamber that can contain one or more work pieces therein and to receive a heat-exchange liquid that comes into contact with the one or more work pieces to allow heat exchange with the one or more work pieces. The vacuum pump can exhaust at least a portion of the vapor evaporated from the heat-exchange liquid on the work pieces or in the container. The vacuum chamber includes a deposition source unit can provide material to be deposited on the one or more work pieces in vacuum. The one or more work pieces can be brought a predetermined temperature by the heat-exchange liquid.

Implementations of the system may include one or more of the following. The vacuum processing system can further include a first fluid conduit that can introduce the heat-exchange liquid into the container; and a fluid pump that can to pump the heat-exchange liquid into the first fluid conduit. The vacuum processing system can further include a heat exchange unit that can control the temperature of the heat-exchange fluid to heat or cool the work pieces. The vacuum processing system can further include a second fluid conduit that can remove the heat-exchange liquid from the container. The one or more work pieces can be cooled by the evaporation of the heat-exchange liquid. The vacuum processing system can further include a stirrer that can produce a movement in the heat-exchange liquid to assist the evaporation of the heat-exchange liquid. The one or more work pieces can include irregular surfaces. The one or more work pieces can include printed circuit board. The vacuum pump can exhaust the vapor evaporated from the heat-exchange liquid on the work pieces to produce dry clean surfaces on the work pieces to allow deposition of the material on the one or more work pieces. The heat-exchange liquid can include alcohol, methanol, isopropyl alcohol, water, heat-exchange liquid nitrogen, heat-exchange liquid oxygen, or gasoline.

In another general aspect, the present invention relates to a method for vacuum processing a work piece at a pre-determined temperature that includes placing one or more work pieces in a container in a vacuum chamber; introducing a heat-exchange liquid in the container to come into contact with the one or more work pieces, which allows the heat-exchange liquid to exchange heat with the one or more work pieces to bring the one or more work pieces to a predetermined temperature; exhausting air and vapor evaporated from the heat-exchange liquid in the vacuum chamber; and depositing, in vacuum, a material from a deposition source unit on the one or more work pieces at the pre-determined temperature.

Implementations of the system may include one or more of the following. The method can further include pumping the heat-exchange liquid into the container by a fluid pump. The method can further include controlling the temperature of the heat-exchange fluid by a heat exchange unit to heat or cool the work pieces. The method can further include removing the heat-exchange liquid from the container after the one or more work pieces are brought to the predetermined temperature. The method can further include cooling the one or more work pieces by the evaporation of the heat-exchange liquid. The method can further include stirring the heat-exchange liquid to assist the evaporation of the heat-exchange liquid. The one or more work pieces can include irregular surfaces. The one or more work pieces can include printed circuit board. The method can further include exhausting the vapor evaporated from the heat-exchange liquid on the work pieces to produce dry clean surfaces on the work pieces to allow deposition of the material on the one or more work pieces. The heat-exchange liquid can include alcohol, methanol, isopropyl alcohol, water, heat-exchange liquid nitrogen, heat-exchange liquid oxygen, or gasoline.

The details of one or more embodiments are set forth in the accompanying drawings and in the description below. Other features, objects, and advantages of the invention will become apparent from the description and drawings, and from the claims.

### BRIEF DESCRIPTION OF THE DRAWINGS

FIG. 1 shows a perspective view of a vacuum processing system providing effective cooling and heating in accordance with the present invention.

FIG. 2 is a perspective of the vacuum processing system of FIG. 1 without the upper cover.

FIG. 3 shows a perspective cross-sectional view of the vacuum processing system of FIG. 1.

FIG. 4 is a cross-sectional view of the vacuum processing system of FIG. 1 showing a container filled with a heat-exchange liquid.

FIG. 5 is a cross-sectional view of the vacuum processing system of FIG. 1 showing the heat-exchange liquid being removed from the container.

FIG. 6 is a flowchart for providing effective cooling in a vacuum processing system in accordance with the present invention.

FIG. 7 is a flowchart for providing effective heating in a vacuum processing system in accordance with the present invention.

### DETAILED DESCRIPTION OF THE INVENTION

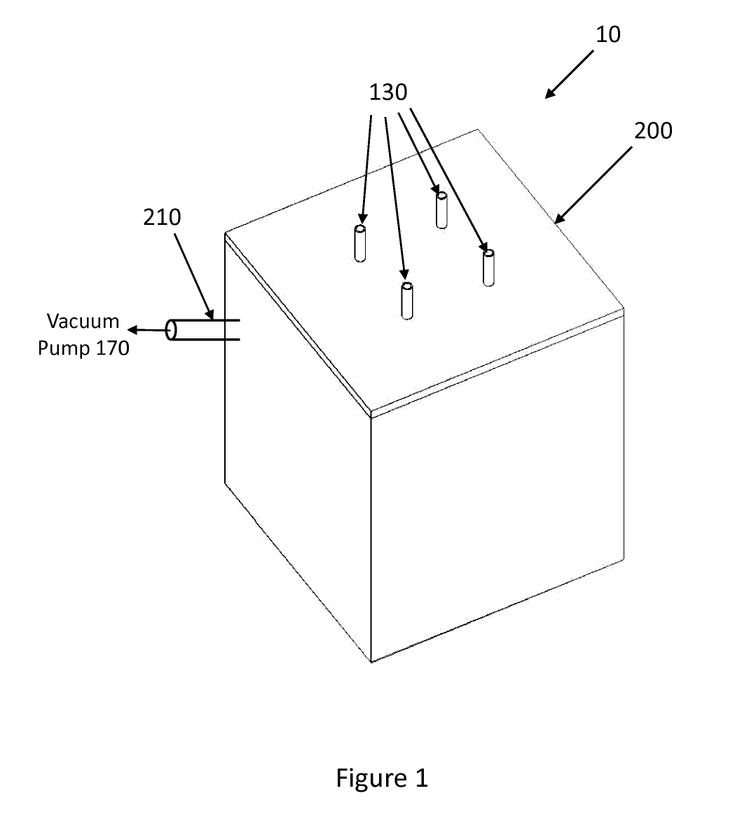

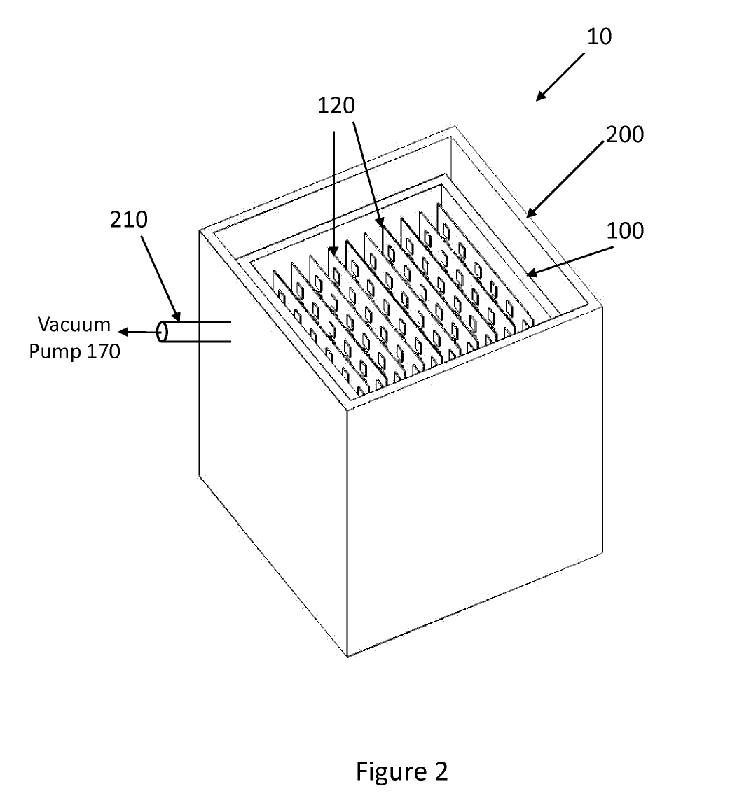

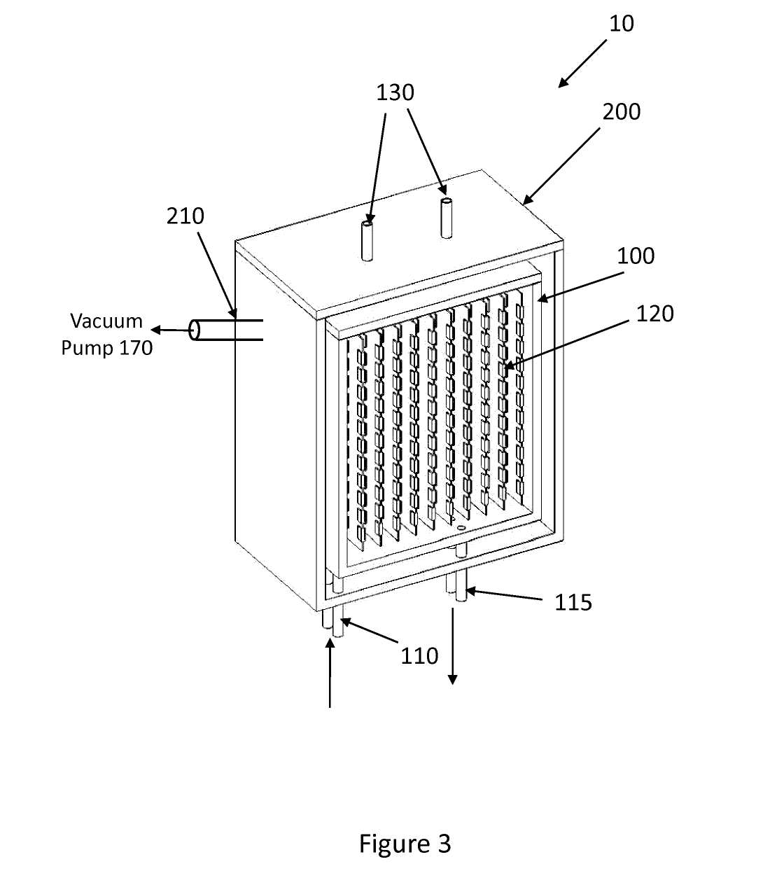

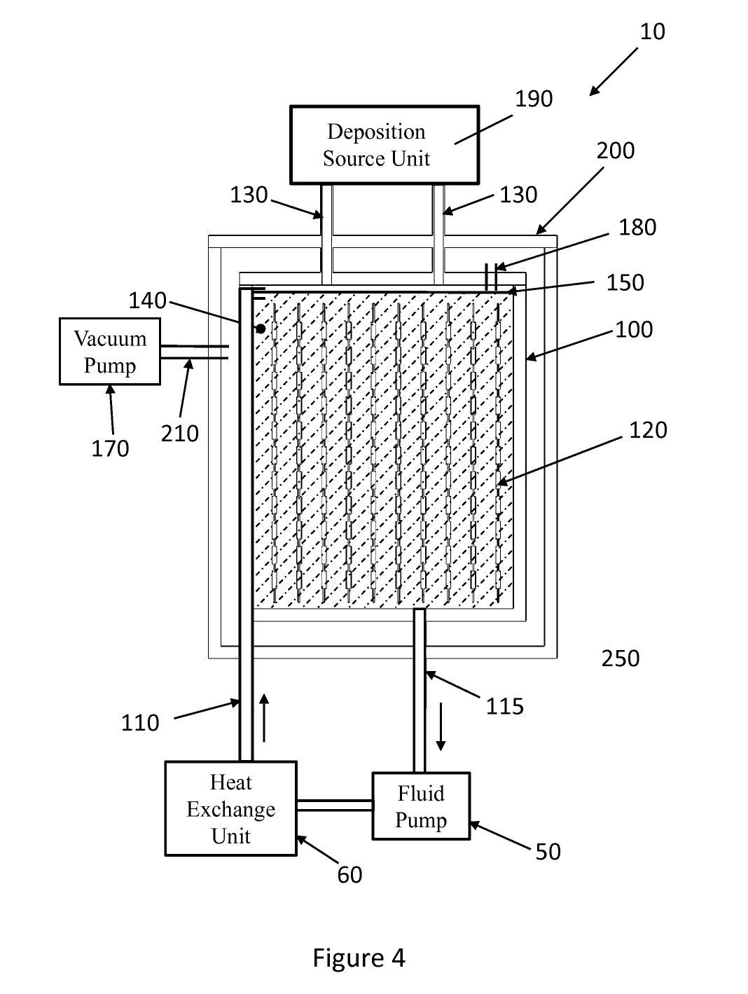

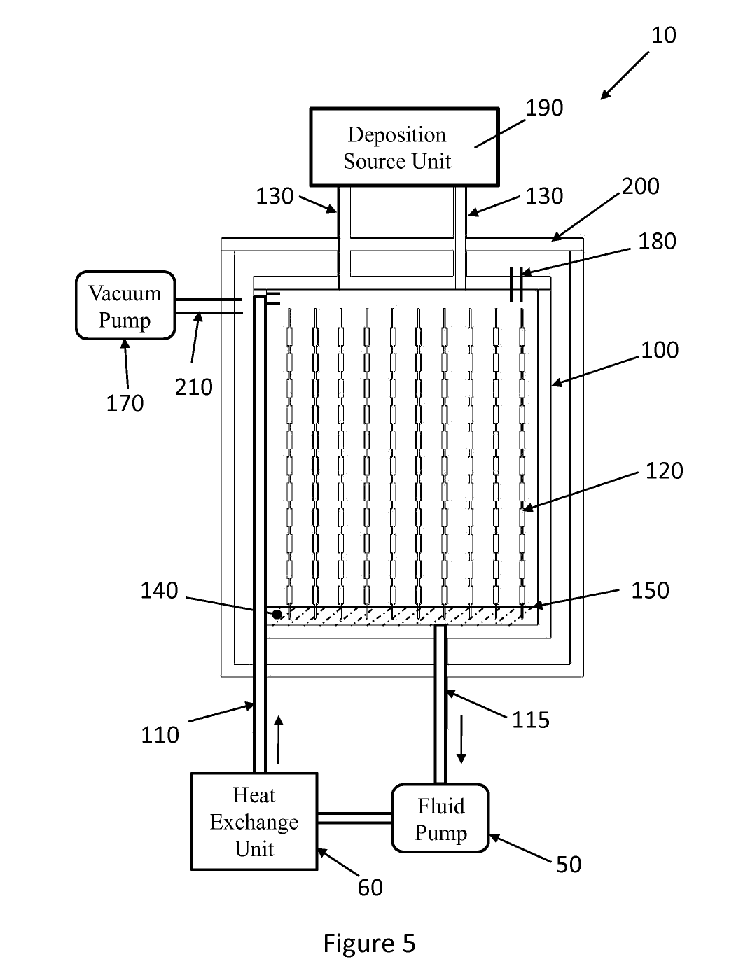

Referring FIGS. 1-5, a vacuum system 10 includes a container 100 placed inside the vacuum chamber 200. The vacuum chamber 200 includes an air outlet 210 that is connected to a vacuum pump 170 that is configured to exhaust air from the vacuum chamber 200 to produce a vacuum environment in the vacuum chamber 200. The container 100 includes an air channel 180 that allows the vacuum pump 170 to exhaust air or vapor out of the container 100.

The container 100 can hold one or more work pieces 120 inside. The work pieces 120 can have irregular surface shapes. For example, the work pieces 120 can be PCBs that need to be deposited with a protective coating made of fluorine containing polymer in a vacuum environment. In this example, it is preferred to have the depositions to be conducted at a temperature lower than room temperature in order to increase the deposition rate. Thus the work pieces 120 need to be cooled before the deposition of to −30° C.

The vacuum system 10 includes a deposition source units 190 configured to provide deposition material for the work pieces 120. For example, the deposition source units 190 can include a target material, a heating element for vaporizing the target material, and a vapor chamber for containing the vapor of the target material. The container 100 includes conduits 130 in connection to (the vapor chamber of) the deposition source units 190 for introducing the deposition material into the container 100 and to be deposited onto the work pieces 120.

In accordance with the present invention, the container 100 also includes an inlet 110 and an outlet 115 which are connected to a fluid pump 50 and a heat exchange unit 60 in the vacuum system 10. The fluid pump 50 can pump a heat-exchange liquid 140 into the container 100 through the inlet 110 and draw out the heat-exchange liquid 140 through the outlet 115.

The heat exchange unit 60 is configured to lower or raise the temperature of the heat-exchange liquid 140 to a pre-determined temperature depending on the desirable temperature for the work pieces 120 during material deposition. For cooling, the pre-determined temperature of heat-exchange liquid 140 can be lower than the desired temperature of the work pieces 120. For heating, the pre-determined temperature of heat-exchange liquid 140 can be higher than the desired temperature of the work pieces 120. The heat-exchange liquid 140 can include alcohol, methanol, isopropyl alcohol (IPA), water, heat-exchange liquid nitrogen, heat-exchange liquid oxygen, gasoline or others, which are easy to evaporate and have significant latent heat. The heat-exchange liquid 140 is of high purity and does not contaminate the work pieces 120.

The heat-exchange liquid 140 is pumped into the container 100 to come into contact with the work pieces 120. The work pieces 120 can be submerged in the heat-exchange liquid 140 in the container 100, which allows the heat-exchange liquid 140 to transfer heat to or away from the work pieces 120 without chemically reacting or damaging the work pieces 120. The work pieces 120 can be cooled down or heated up by different methods the before deposition or other process of the work pieces 120.

In one implementation, the vacuum chamber 200 is evacuated by the vacuum pump 170 via the air outlet 210. The heat-exchange liquid 140 evaporates in the container and the resulting vapor is exhausted by the vacuum pump 170 via the air channel 180 and the air outlet 210. The heat loss during the evaporation of the heat-exchange liquid 140 lowers down the temperature of the heat-exchange liquid 140 and by heat exchange, also the temperatures of the work pieces 120. The heat-exchange liquid 140 can be entirely evaporated, or partially pumped out after evaporation. The heat-exchange liquid 140 has high purity and can thus leave dry clean surfaces on the work pieces 120. In this implementation, the heat-exchange liquid 140 can optionally be pumped into the container by the fluid pump 50. Alternatively, the fluid pump 50 and heat exchange unit 60 are not needed in the vacuum system 10; the heat-exchange liquid 140 can be introduced to the container when the vacuum chamber 200 and the container 100 are both open to outside. After the work pieces 120 are cooled down to the desired temperature, the heat-exchange liquid 140 can drained out by gravity or evaporated by the vacuum pump 170 via the air outlet 210.

In some embodiments, the evaporation of the heat-exchange liquid 140 and thus the cooling can be accelerated by the movement of a stirrer (not shown) submerged in the heat-exchange liquid 140.

In another implementation, the vacuum chamber 200 including the inside of the chamber 100 is evacuated by the vacuum pump 170 via the air outlet 210. The heat-exchange liquid 140 is cooled or heated to a preset temperature by the heat exchange unit 60 before, during, or after the vacuum evacuation. The heat-exchange liquid 140 is pumped by the fluid pump 50 into the container 100 and circulated to allow the work pieces 120 to reach the preset temperature. Afterwards, the heat-exchange liquid 140 can be pumped out via outlet 115 and/or evaporated via the air channel 180 to leave dry clean surfaces on work pieces 120.

After the work pieces 120 reach the pre-set temperature and the heat-exchange liquid 140 removed from the container 100 by the fluid pump 50 or by evaporation and exhaustion by the vacuum pump 170, the work piece 120 can be processed. The deposition material can be introduced from the deposition source unit 190 into the container 100 through the conduits 130 for deposit on the work pieces 120. The temperature of the work pieces 120 sometimes cannot be maintained during the deposition. For example, the work pieces 120 can be heated up by the vapor of the deposition. The processing of the work pieces 120 can be temporarily stopped. The heat-exchange liquid 140 can be pumped back into the container 100 to repeat the cooling/heating procedure.

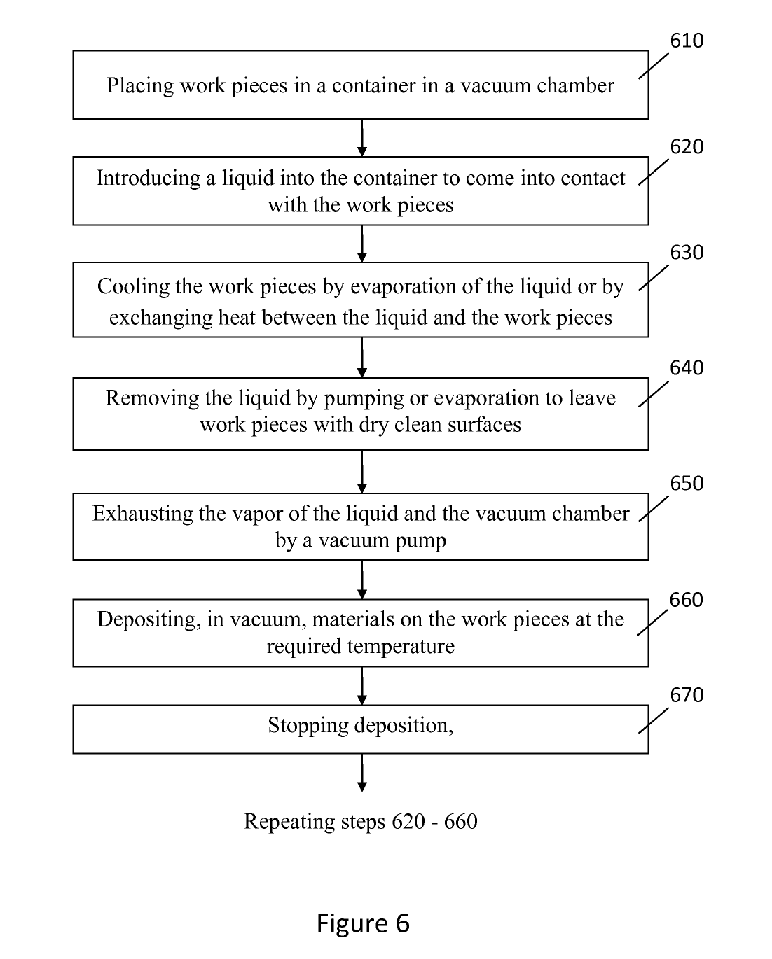

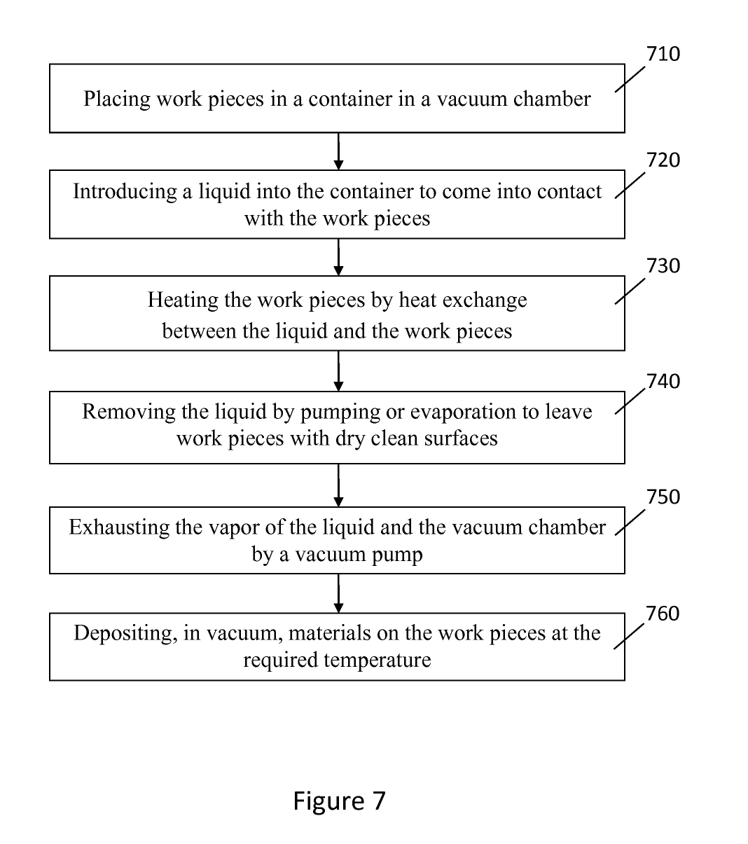

Referring to FIG. 6, the cooling of work pieces in a vacuum system can include the following steps in accordance with the present invention. The work pieces are placed in a container in a vacuum chamber (step 610). A high-purity heat-exchange liquid is introduced into the container to come into contact with the work pieces (step 620). The work pieces can be cooled by evaporation of the heat-exchange liquid which is exhausted by a vacuum pump out of the vacuum chamber (step 630). The work pieces can be cooled by exchanging heat between the heat-exchange liquid and the work pieces (step 630), in which case the heat-exchange liquid can be maintained at a pre-set temperature by a heat exchange unit outside the container. The heat-exchange liquid is then removed by pumping and/or evaporation to leave work pieces with dry clean surfaces (step 640). The vapor of the remaining heat-exchange liquid in the container and the vacuum chamber is exhausted by the vacuum pump (step 650). Material can be deposited in vacuum o the work pieces at the required temperatures (step 660). If the temperatures of the work pieces rise during the deposition, deposition can be temporarily stopped (step 670). The heat-exchange liquid can be pumped back into the container to repeat steps 620-660. Referring to FIG. 7, the heating of work pieces in a vacuum system can include the following steps in accordance with the present invention. The work pieces are placed in a container in a vacuum chamber (step 710). A high-purity heat-exchange liquid is introduced into the container to come into contact with the work pieces (step 720). The work pieces can be heated by exchanging heat between the heat-exchange liquid and the work pieces (step 730), in which case the heat-exchange liquid can be maintained at a pre-set temperature by a heat exchange unit outside the container. The heat-exchange liquid is then removed by pumping and/or evaporation to leave work pieces with dry clean surfaces (step 740). The vapor of the remaining heat-exchange liquid in the container and the vacuum chamber is exhausted by the vacuum pump (step 750). Material can be deposited in vacuum o the work pieces at the required temperatures (step 760).

It is understood that the disclosed systems are compatible with many different types of processing operations such as physical vapor deposition (PVD), thermal evaporation, thermal sublimation, sputtering, CVD, PECVD, ion etching, or sputter etching. The disclosed processing systems can include other components such as load lock, transport mechanism for the substrates, etc. without deviating from the spirit of the invention. The deposition materials can be provided by sputtering targets, gas distribution device, and other types of source units without deviating from the spirit of the invention.

What is claimed is:

1. A vacuum processing system, comprising:
a vacuum chamber in connection with a vacuum pump that is configured to exhaust air or vapor in the vacuum chamber;
a container in the vacuum chamber configured to contain one or more work pieces therein and to receive a heat-exchange liquid that comes into contact with the one or more work pieces to allow heat exchange with the one or more work pieces, wherein the vacuum pump is configured to exhaust at least a portion of the vapor evaporated from the heat-exchange liquid on the work pieces or in the container; and
a deposition source unit configured to provide material to be deposited on the one or more work pieces in vacuum, wherein the one or more work pieces are brought a predetermined temperature by the heat-exchange liquid.

2. The vacuum processing system of claim 1, further comprising:
a first fluid conduit configured to introduce the heat-exchange liquid into the container; and
a fluid pump configured to pump the heat-exchange liquid into the first fluid conduit.

3. The vacuum processing system of claim 2, further comprising:
a heat exchange unit configured to control the temperature of the heat-exchange fluid to heat or cool the work pieces.

4. The vacuum processing system of claim 1, further comprising a second fluid conduit configured to remove the heat-exchange liquid from the container.

5. The vacuum processing system of claim 1, wherein the one or more work pieces are cooled by the evaporation of the heat-exchange liquid.

6. The vacuum processing system of claim 5, further comprising a stirrer configured to produce a movement in the heat-exchange liquid to assist the evaporation of the heat-exchange liquid.

7. The vacuum processing system of claim 1, wherein the one or more work pieces comprise irregular surfaces.

8. The vacuum processing system of claim 7, wherein the one or more work pieces comprise printed circuit board.

9. The vacuum processing system of claim 1, wherein the vacuum pump is configured to exhaust the vapor evaporated from the heat-exchange liquid on the work pieces to produce dry clean surfaces on the work pieces to allow deposition of the material on the one or more work pieces.

10. The vacuum processing system of claim 1, wherein the heat-exchange liquid comprises alcohol, methanol, isopropyl alcohol, water, heat-exchange liquid nitrogen, heat-exchange liquid oxygen, or gasoline.

11. A method for vacuum processing a work piece at a pre-determined temperature, comprising:
placing one or more work pieces in a container in a vacuum chamber;
introducing a heat-exchange liquid in the container to come into contact with the one or more work pieces, which allows the heat-exchange liquid to exchange heat with the one or more work pieces to bring the one or more work pieces to a predetermined temperature;
exhausting air and vapor evaporated from the heat-exchange liquid in the vacuum chamber; and
depositing, in vacuum, a material from a deposition source unit on the one or more work pieces at the pre-determined temperature.

12. The method of claim 11, further comprising:
pumping the heat-exchange liquid into the container by a fluid pump.

13. The method of claim 12, further comprising:
controlling the temperature of the heat-exchange fluid by a heat exchange unit to heat or cool the work pieces.

14. The method of claim 11, further comprising:
removing the heat-exchange liquid from the container after the one or more work pieces are brought to the predetermined temperature.

15. The method of claim 11, further comprising:
cooling the one or more work pieces by the evaporation of the heat-exchange liquid.

16. The method of claim 15, further comprising:
stirring the heat-exchange liquid to assist the evaporation of the heat-exchange liquid.

17. The method of claim 11, wherein the one or more work pieces comprise irregular surfaces.

18. The method of claim 17, wherein the one or more work pieces comprise printed circuit board.

19. The method of claim 11, further comprising:
exhausting the vapor evaporated from the heat-exchange liquid on the work pieces to produce dry clean surfaces on the work pieces to allow deposition of the material on the one or more work pieces.

20. The method of claim 11, wherein the heat-exchange liquid comprises alcohol, methanol, isopropyl alcohol, water, heat-exchange liquid nitrogen, heat-exchange liquid oxygen, or gasoline.
